(19) United States
(12) Patent Application Publication
(10) Pub. No.: US 2026/0050699 A1
(43) Pub. Date: Feb. 19, 2026

(54) SYSTEMS AND METHODS FOR GENERATING SYNTHETIC DATA FOR TRAINING MACHINE LEARNING MODELS

(71) Applicant: SYNTHETIK APPLIED TECHNOLOGIES, LLC., Austin, TX (US)

(72) Inventors: John Hawkins, Kaneche, HI (US); Wesley Welch, Brandon, MS (US); Jacob Hoehler, Cincinnanti, OH (US); Ryan Jalufka, Portland, OR (US)

(21) Appl. No.: 19/301,802

(22) Filed: Aug. 15, 2025

Related U.S. Application Data
(60) Provisional application No. 63/684,068, filed on Aug. 16, 2024.

(51) Int. Cl. G06F 30/10

(52) U.S. Cl. CPC G06F 30/10

(57) ABSTRACT

Systems and methods for generating a large volume of synthetic stream-of-commerce security imaging data is disclosed. Methods for creating synthetic baggage x-ray scans, synthetic passenger millimeter wave scans, synthetic passenger video surveillance data, and introducing prohibited items to real security images are also disclosed.

### REFERENCE TO RELATED APPLICATION

The present application claims priority to U.S. Provisional Patent Application No. 63/684,068 to Hawkins, et al., entitled “SYSTEMS AND METHODS FOR GENERATING SYNTHETIC DATA FOR TRAINING MACHINE LEARNING MODELS,” filed on Aug. 16, 2024, the entirety of which is fully incorporated by reference herein.

### STATEMENT OF GOVERNMENT INTEREST

This invention was made with Government support under Contract Nos. 70RSAT19C00000032, 70RSAT22C00000059, 70RSAT19T00000016, 70RSAT20C00000014, 70RSAT20T00000021, 70RSAT21T00000015, 70RSAT22T00000016, and 70RSAT25C00000024 awarded by the United States Department of Homeland Security. The Government has certain rights in the invention.

### BACKGROUND OF THE DISCLOSURE

### Field of the Disclosure

This disclosure generally relates to systems and methods for generating synthetic data (i.e., human-style responses or results) regarding baggage x-ray and passenger millimeter wave security screening images and surveillance video.

### Description of the Related Art

Various governmental agencies and private organizations are tasked with ensuring safe travel and commerce. In an effort to provide adequate safety during travel, these agencies and organizations continually enhance their technological capabilities. These capabilities currently include metal detectors, millimeter wave passenger scanners, x-ray computed tomography (CT) baggage scanners, and video surveillance cameras. These technologies are used to identify prohibited items that could jeopardize travel safety. Non-limiting examples include knives, firearms, explosives, and explosive making material. The output from each of these devices can be inspected by authorized personnel who are trained in the identification of prohibited items. However, such efforts by the respective agencies and organizations are very costly and require a large amount of human intervention due to false positives. Furthermore, due to privacy concerns with millimeter wave imaging on the human body, manual human inspection of these images is prohibited, and inspection is therefore entirely automated.

Systems for simulating x-ray CT scans, millimeter wave scans, and surveillance video of three-dimensional (3D) objects in order to develop synthetic datasets are being researched. For example, such systems may be designed to generate synthetic scans of baggage or passengers to help train automatic threat recognition algorithms. In the context of security, new threats are constantly emerging, and it is essential to keep threat recognition algorithms up to date. However, generation of real data can be expensive, time consuming, and limited. For example, one way to generate real data is to scan a real baggage containing a target object along with other travel objects. Further, multiple scans of such baggage for the single target object may be performed as the target object may be stored in different locations, configurations, and orientations in a real-world setting. Such scans may be necessary for each target object that is to be identified. Accordingly, the amount of manual scanning that may be required for building up a reference database may be quite extensive, requiring heavy usage of resources, both technical and human. These resources include human manual ground truth annotation to support supervised learning tasks. Furthermore, such manual configurations and subsequent scanning may be unable to capture a sufficient number of variations for accurately detecting the target object. Therefore, utilization of synthetic data can help decrease costs, increase speed, increase detection accuracy, and result in large amounts of useable data.

### SUMMARY OF THE DISCLOSURE

One embodiment of a system for generating a large volume of synthetic stream-of-commerce security imaging data according to the present disclosure includes (1) a user interface configured to accept a user's specification of modeling parameters and simulation parameters and (2) a non-transitory computer-readable media operably connected to the user interface and encoding a set of non-transitory computer-readable instructions. These instructions, which when executed on one or more processors, cause inputting the specification of modeling parameters and simulation parameters, generation of synthetic scans, performance of 3D modeling and simulation to generate randomized models based on the modeling parameters; passing of the randomized models to physics-based simulation codes for generating simulated image system outputs based on the simulation parameters, and generation of ground truth annotations of the randomized models based on the modeling parameters and simulation parameters.

One embodiment of a non-transitory computer-readable media encoding a set of non-transitory computer-readable instructions according to the present disclosure, when executed on one or more processors, cause the inputting of user specification of modeling parameters and simulation parameters; generation of synthetic scans; performance of 3D modeling and simulation to generate randomized models based on the modeling parameters; passing of the randomized models to physics-based simulation codes for generating simulated image system outputs based on the simulation parameters; and generation of ground truth annotations of the randomized models based on the modeling parameters and simulation parameters.

One method for creating synthetic scans according to the present disclosure includes obtaining a real scan and a synthetic scan having a prohibited item; using a clustering algorithm to isolate voxelized masks of unique objects and empty space in the real scan; using a truth segmentation mask to isolate the voxel representation of the prohibited item from the synthetic scan; applying a 3D bin packing algorithm to determine the location in which the prohibited item may fit in the real scan; performing augmentation on the prohibited item; inserting the prohibited item in the voxelized masks to create a modified scan; and saving the modified scan for use in model training.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other systems or methods for carrying out the same purposes of the present disclosure.

These and other further features and advantages of the disclosure would be apparent to those skilled in the art from the following detailed description, taken together with the accompanying drawings, wherein like numerals designate corresponding components or steps in the figures, in which:

### BRIEF DESCRIPTION OF THE DRAWINGS

FIGS. 1A-1E illustrate various interfaces for generating synthetic data in accordance with an exemplary embodiment of the present disclosure.

FIG. 1F illustrates a block diagram of a system for generating synthetic data regarding baggage x-ray, passenger millimeter wave security screening, and video images according to an embodiment of the present disclosure.

FIG. 1G shows exemplary ground truth annotations generated as part of a method for creating synthetic data regarding baggage x-ray, passenger millimeter wave, and video surveillance security screening images according to an embodiment of the present disclosure.

FIGS. 2A-2D illustrate synthetic x-ray imaging in accordance with an exemplary embodiment.

FIGS. 3A-3G illustrate synthetic millimeter wave and video surveillance imaging in accordance with an exemplary embodiment.

FIG. 4A is a flow chart of a method of generating hybrid synthetic datasets according to an embodiment of the present disclosure.

FIG. 4B shows one example of operation 407 of the method of FIG. 4A according to an embodiment of the present disclosure.

### DETAILED DESCRIPTION OF THE DISCLOSURE

In the description that follows, numerous details are set forth in order to provide a thorough understanding of the disclosure. It will be appreciated by those skilled in the art that variations of these specific details are possible while still achieving the results of the disclosure. Well-known elements, steps, algorithms, regression models, and processing steps are generally not described in detail in order to avoid unnecessarily obscuring the description of the disclosure.

Throughout this description, the preferred embodiments and examples illustrated should be considered as exemplars, rather than as limitations on the present disclosure. As used herein, the terms “invention,” “disclosure,” “method,” “present invention,” “present disclosure,” “present method,” or similar terms refer to any one of the embodiments of the disclosure described herein, and any equivalents. Furthermore, reference to various feature(s) of the “invention,” “disclosure,” “method,” “present invention,” “present disclosure,” “present method,” or similar terms throughout this document does not mean that all claimed embodiments or methods must include the referenced feature(s).

Additionally, various algorithms and machine learning (ML) techniques are described herein. It is understood that different algorithms and/or ML techniques (e.g., federated learning, Kriging, etc.) could potentially be used as would be understood by one of skill in the art, and thus fall within the scope of the present disclosure. Any specific algorithm discussed herein could potentially be replaced by another algorithm, whether currently existing or later developed, as would be understood by one of skill in the art.

Although the terms first, second, etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

As used herein, the term “and/or” includes any and all combinations of one or more of the associated list items. The term “and” should also be able to be understood exclusively, and the term “or” understood inclusively, so as to bring within the scope of the disclosure all embodiments that would be understood by one of skill in the art.

The terminology used herein is for describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” “including,” and similar terms, when used herein, specify the presence of stated features, algorithms, steps, operations, elements, and/or components, but do not preclude the presence or addition of one or more other features, algorithms, steps, operations, elements, components, and/or groups thereof.

The steps described in the below methods may be performed in different orders than those specifically described, as would be understood by one of skill in the art. Some steps may be performed simultaneously and/or continuously, as would be understood by one of skill in the art.

Numerous specific details are set forth in order to provide a more thorough understanding of embodiments incorporating features of the present disclosure. However, it will be apparent to one skilled in the art that the present disclosure can be practiced without necessarily being limited to these specifically recited details.

Embodiments of the disclosure are described herein with reference to flowcharts that are schematic illustrations of specific embodiments of the disclosure. As such, the arrangements of components or steps can be different, and variations are expected. Additionally, components and steps shown as a singular component or step may include multiple components or substeps, while aspects shown as multiple components or steps may be a singular component or performed as a singular step. Embodiments of the disclosure should not be construed as limited to the particular arrangements, components, or steps.

Furthermore, any element in a claim that does not explicitly state “means for” performing a specified function, or “step for” performing a specific function, is not to be interpreted as a “means” or “step” clause as specified in 35 U.S.C. § 112, for example, in 35 U.S.C. § 112(f) or pre-AIA 35 U.S.C. § 112, sixth paragraph.

All the features disclosed in this application may be replaced by alternative features serving the same, equivalent or similar purpose, unless expressly stated otherwise. Thus, unless expressly stated otherwise, each feature disclosed is one example only of a generic series of equivalent or similar features.

One of the advances of the current technological age is the advent of ML, an important subset in the field of artificial intelligence (AI). ML may be used to inform the detection and type of prohibited item identified during passenger and baggage screening. Although humans can be trained to detect these items, the low frequency of a passenger bringing these items, as well as bad actors' attempts to hide the items, may make human detection alone somewhat risky and potentially error prone. This risk coupled with the extreme impact of one of these prohibited items being missed during screening, as well as the time it takes for a human inspector to perform an unassisted inspection, makes it necessary to have as much redundancy as possible for security screening. With automatic detection by intelligent systems, humans can reserve extended review for scans of passengers or baggage of particular interest. More specifically, by performing initial detection using a ML algorithm, only the passengers or baggage that are flagged by the ML algorithm may require extended review for prohibited items by human inspectors.

Although ML algorithms can be invaluable in the detection of prohibited items, the algorithms must be developed using training data with both positive and negative control sets. This training data typically includes scans of actual explosives, explosive making material, or weapons. Creating these positive scans (e.g., scans with actual explosives, explosive making material, etc.) may be very time consuming, costly, and in some cases, dangerous. It is also difficult to create comprehensive sets for each type of prohibited item in baggage with different clutter levels or on passengers with different anthropometric measurements. For this reason, systems and methods for increasing the positive control data sets could vastly improve ML algorithm development. In this regard, high-quality synthetic data is desired for increased efficacy and faster deployment of effective ML technologies with respect to passenger and baggage screening.

According to exemplary aspects, AI or ML algorithms may be executed to perform data pattern detection, and to provide an output based on the data pattern detection. More specifically, an output may be provided based on a historical pattern of data, such that with more data or more recent data, more accurate outputs may be provided. Accordingly, the ML or AI models may be constantly updated after a predetermined number of runs or iterations. According to exemplary aspects, ML may refer to computer algorithms that may improve automatically through use of data. ML algorithm may build an initial model based on sample or training data, which may be iteratively improved upon as additional data are acquired.

More specifically, ML/AI and pattern recognition may include supervised learning algorithms such as, for example, regression analysis, decision tree analysis, random forest analysis, k-nearest neighbors analysis, logistic regression analysis, 5-fold cross-validation analysis, balanced class weight analysis, and the like. In another exemplary embodiment, ML analytical techniques may include unsupervised learning algorithms such as, for example, Apriori analysis, k-means clustering analysis, etc. In another exemplary embodiment, ML analytical techniques may include reinforcement learning algorithms such as, for example, Markov Decision Process analysis, and the like.

In another exemplary embodiment, the ML or AI model may be based on a ML algorithm. The ML algorithm may include at least one from among a process and a set of rules to be followed by a computer in calculations and other problem-solving operations such as, for example, a linear regression algorithm, a logistic regression algorithm, a decision tree algorithm, and/or a Naive Bayes algorithm.

In another exemplary embodiment, the ML or AI model may include training models such as, for example, a ML model which is generated to be further trained on additional data. Once the training model has been sufficiently trained, the training model may be deployed onto various connected systems to be utilized. In another exemplary embodiment, the training model may be sufficiently trained when model assessment methods such as, for example, a holdout method, a K-fold-cross-validation method, and a bootstrap method determine that at least one of the training model's least squares error rate, true positive rate, true negative rate, false positive rate, and false negative rates are within predetermined ranges.

In another exemplary embodiment, the training model may be operable, i.e., actively utilized by an organization, while continuing to be trained using new data. In another exemplary embodiment, the ML or AI models may be generated using at least one from among an artificial neural network technique, a decision tree technique, a support vector machines technique, a Bayesian network technique, and a genetic algorithms technique.

As one of skill in the art would understand, although the various systems and methods disclosed herein are described with reference to various imaging modalities, e.g., x-ray, CT, millimeter wave, video surveillance, etc., the systems and methods disclosed herein can be utilized in conjunction with other imaging modalities not expressly recited herein. Accordingly, the imaging modalities described herein are exemplary in nature and not intended to limit the scope of this disclosure. Relatedly, the term “scan” is understood to encompass the output of a wide variety of imaging modalities and is not intended to limit the scope of this disclosure. For the avoidance of doubt, “scan” includes images, videos, and other imaging outputs.

### Systems for Producing a Volume of Synthetic Stream-of-Commerce Data

According to exemplary aspects of the present disclosure, a modeling and simulation system may be utilized to build 3D passenger and baggage models, simulate imaging outputs, and generate ground truth annotations for generating a large number of synthetic or virtual baggage and passengers that may serve as training data for the automatic threat recognition algorithms.

In an example, AI or ML algorithms may be executed to perform data pattern detection, and to provide an output based on the data pattern detection. More specifically, an output may be provided based on a historical pattern of data, such that with more data or more recent data, more accurate outputs may be provided. Accordingly, the ML or AI models may be constantly updated after a predetermined number of runs or iterations. According to exemplary aspects, machine learning may refer to computer algorithms that may improve automatically through use of data. Machine learning algorithms may build an initial model based on sample or training data, which may be iteratively improved upon as additional data are acquired.

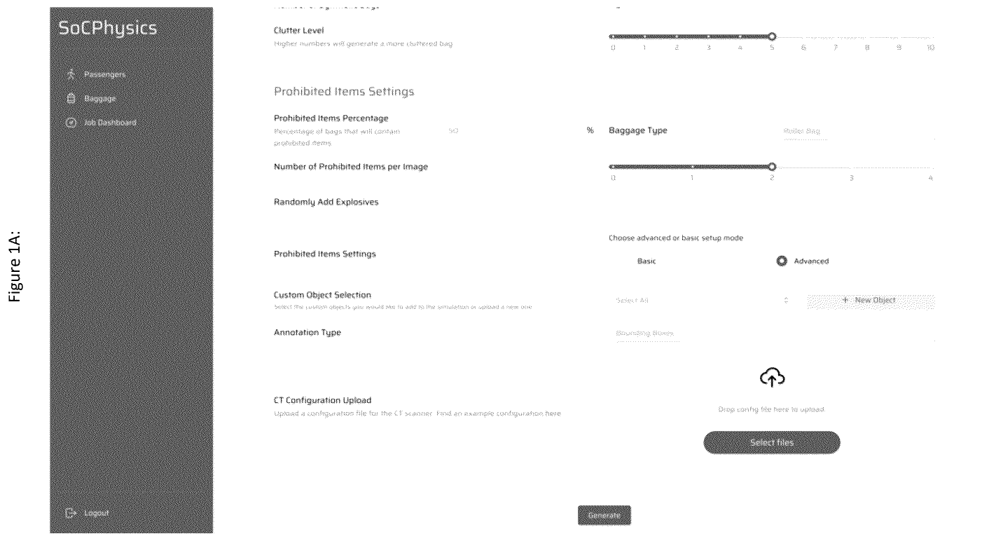

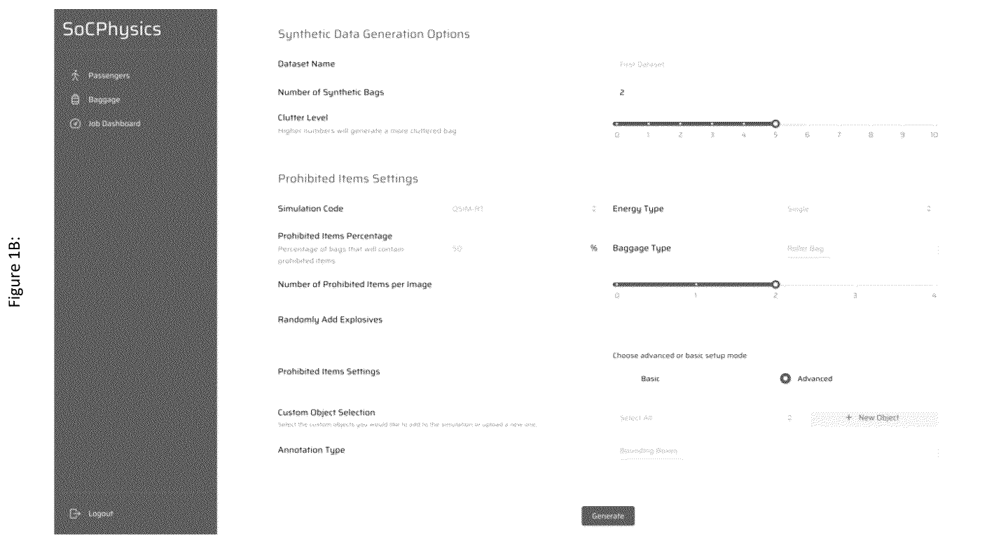

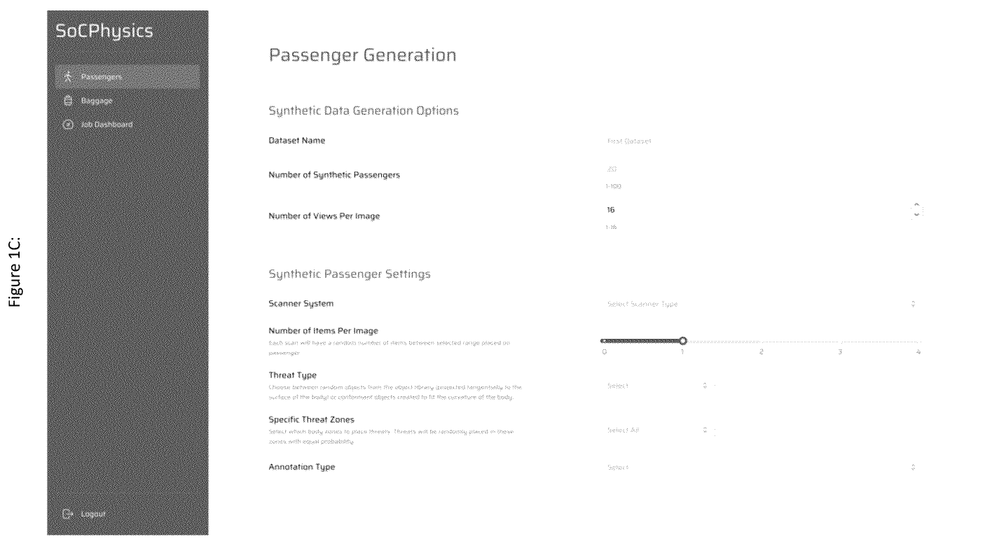

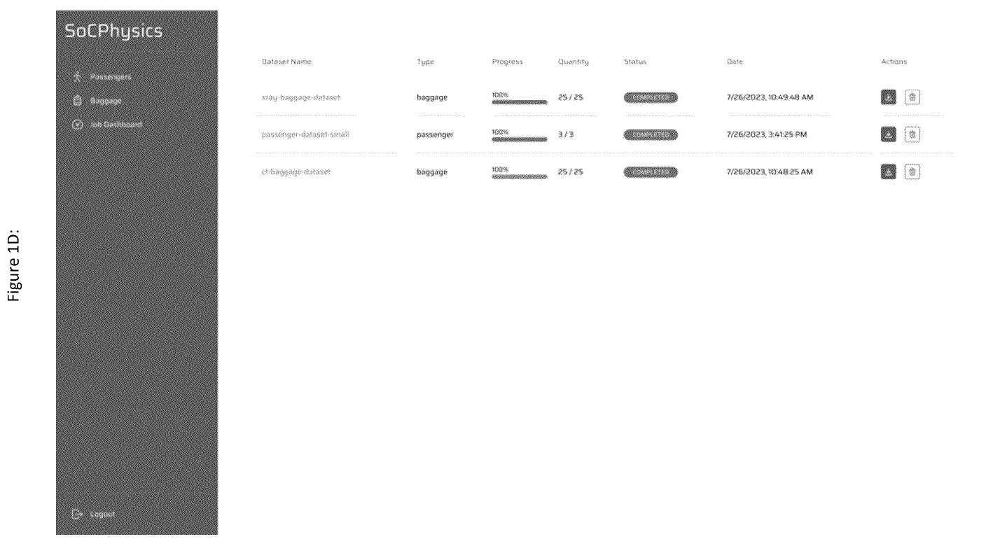

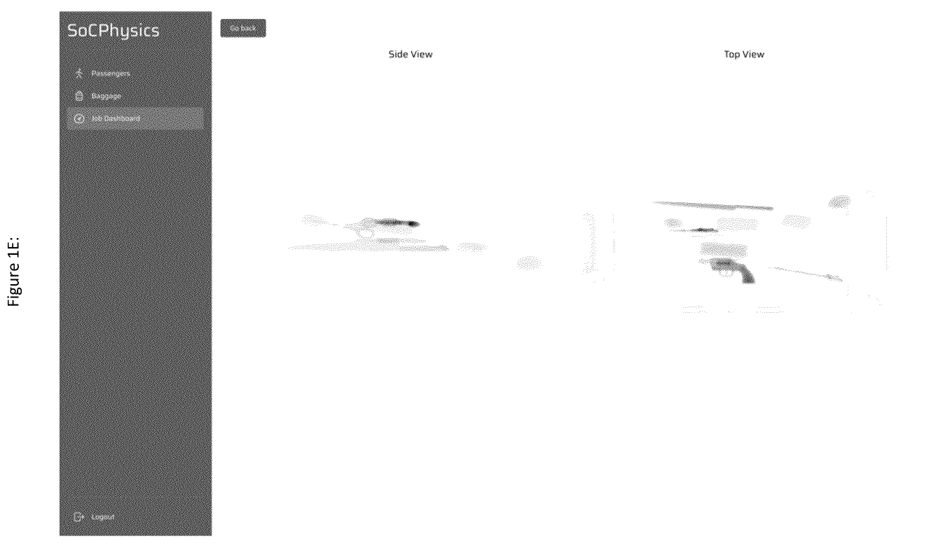

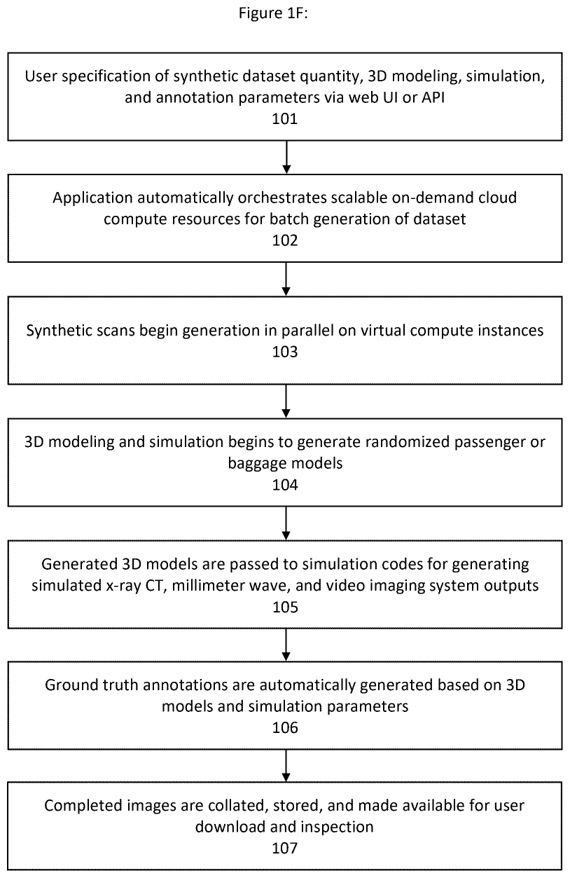

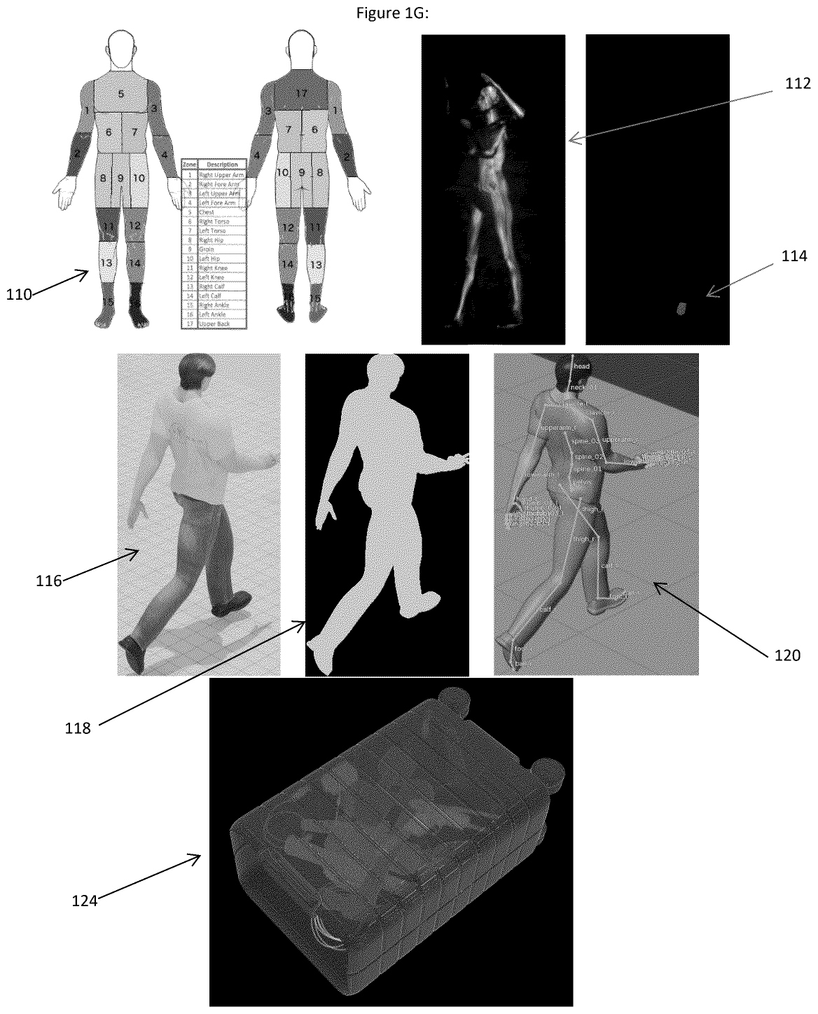

A cloud-based web application may be used in driving the modeling and simulation of synthetic datasets. The application may use scalable cloud compute for dynamically provisioning resources to execute large batch synthetic data generation jobs. The web application User Interface (UI) may support definition, orchestration, monitoring, and interrogation of synthetic datasets and their ground truth annotations. FIGS. 1A-1E illustrate various interfaces for generating synthetic data in accordance with an exemplary embodiment.

FIG. 1A shows one example of how synthetic baggage datasets may be specified using a web UI, including image quantity, prohibited object distributions, ground truth annotation types, and x-ray simulation hardware specifications. As illustrated in FIG. 1B, advanced user settings may be used to specify custom 3D prohibited item models for placement in synthetic datasets. FIG. 1C illustrates that synthetic passenger datasets may likewise be specified using a web UI. As illustrated in FIG. 1D, cloud compute resources and synthetic dataset generation job status may be monitored. The quality and characteristics of synthetically generated datasets may be interrogated using the web UI as shown in FIG. 1E.

FIG. 1F illustrates a block diagram of a system generating simulated baggage or passenger dataset in accordance with an exemplary embodiment. In operation 101, users specify the modeling, simulation and ground truth annotation parameters for dataset generation. In an example, modeling parameters may include benign and prohibited item classes, custom prohibited item model specification, prohibited item distribution, packing algorithm specification, passenger anthropometric measurement distributions, passenger resting pose distribution, and passenger walk cycle animations. In an example, simulation parameters may include source energy spectra, imaging geometry, detector geometry, detector element and transceiver properties, 3D reconstruction algorithms, and material properties. In an example, ground truth annotation parameters may include bounding box, segmentation mask, key point, zone based, and custom annotation formats. This takes place in the web UI or via Application Programming Interface (API).

In operation 102, scalable on-demand cloud compute resources are automatically orchestrated for generation of batch synthetic dataset generation.

In operation 103, synthetic scan generation jobs begin in parallel on scalable cloud compute resources.

In operation 104, 3D modeling and simulation of passengers and baggage begin based on user specified modeling parameters.

In operation 105, generated 3D models are passed to various physics-based simulation codes for generating x-ray CT, millimeter wave, or video imaging system outputs based on user specified simulation parameters.

In operation 106, ground truth annotations of various types are automatically generated and saved based on user specification of modeling and simulation parameters. As illustrated in FIG. 1G, ground truth annotations supported include zone, bounding box, segmentation, key point, and the like, in both 2D and 3D.

As shown in FIG. 1G, some embodiments of systems for generating simulated baggage or passenger datasets can make use of zone annotation 110. In certain embodiments according to the present disclosure, segmentation 114, 118 can be utilized to annotate objects on the person of a passenger 112, 116. Some embodiments of systems annotate passengers 112, 116 using key points 120. As one of skill in the art would understand, various ground truth annotations may be used to annotate baggage scans 124.

In operation 107, completed synthetic datasets are collated, stored, and made available for user download and inspection.

### Synthetic X-Ray Images—Passenger Baggage Modeling

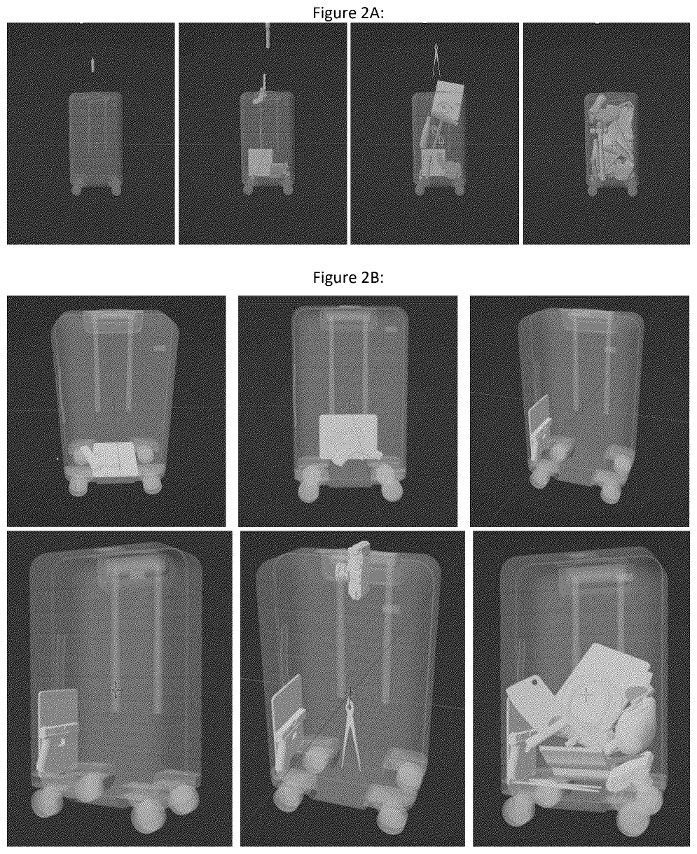

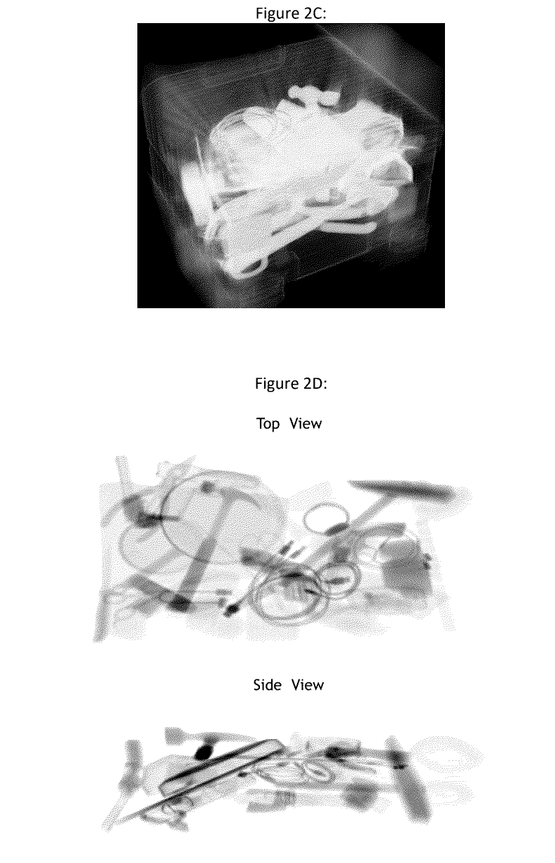

FIGS. 2A-2D illustrate synthetic x-ray CT imaging in accordance with an exemplary embodiment. Simulating synthetic baggage x-ray and x-ray CT data requires access to a large library of three-dimensional (3D) baggage models representative of the wide variation in stream-of-commerce items, prohibited items, and threats seen at security checkpoints. These baggage models also need to be representative of the variations in packing, prohibited item orientation, and prohibited item placement relative to other shield items that may obscure the prohibited item of interest. Generating these representative 3D models is a prerequisite to training robust Automatic Target Recognition (ATR) machine learning models that generalize well in production.

However, generating sufficient number of representative 3D models is a very time-consuming task, and obtaining representative data by physical scanning may be difficult, which may lead to lower accuracy that may not be acceptable in performing security checks or video surveillance. For example, varied 3D models for prohibited items types and their placements in baggage relative to other stream-of-commerce items would need to be captured to serve as proper training data to provide reliable output by the ATR machine learning models. Furthermore, it may be dangerous to generate representative improvised explosive threats and physically scan those samples to generate sufficient training data.

Generating 3D packed baggage models requires large representative libraries of 3D object models and algorithms or methods for determining the placement of those objects relative to each other. Methods for generating individual object placement in 3D space within baggage models are being researched. Volumetric bin packing of arbitrarily shaped 3D objects is an NP-complete problem and various algorithms are being explored. This includes reinforcement learning, simulation, and heuristic based approaches. Simulation offers an approach for generating ample randomization of object placements and orientations with physical realism guarantees and sufficient baggage clutter levels. As illustrated in FIG. 2A, a 3D baggage model may be randomly filled with stream-of-commerce object models and prohibited item models using a rigid body physics simulation with gravity. Furthermore, individual object models may be scaled, skewed and have material property specifications varied to introduce augmentation into the synthetically generated dataset and artificially expand the static library of object models.

Placement of prohibited items may be further controlled to offer guarantees on item orientation and shield occlusion within a synthetically generated dataset. As illustrated in FIG. 2B, prohibited items may be sequentially placed in baggage with specified orientations and occlusion levels prior to filling the remaining baggage with stream-of-commerce items.

Once the placement of individual items has been determined within the baggage item, the models may be converted to different formats in order to interface with a number of x-ray and x-ray CT simulation codes. These formats may include 3D surface mesh models and 3D voxel mesh models. As illustrated in FIG. 2C, the packed baggage models with 3D object placements are saved in a format compatible with 3D x-ray CT simulation codes. As illustrated in FIG. 2D, the packed baggage models with 3D object placements are saved in a format compatible with 2D multi-view x-ray simulation codes.

### Synthetic Millimeter Wave and Video Surveillance Images—Person and Paraphernalia Modeling

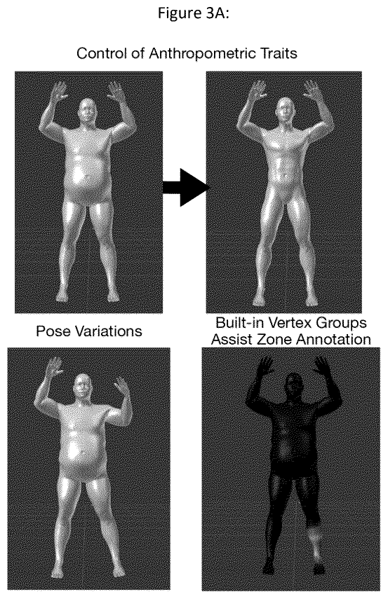

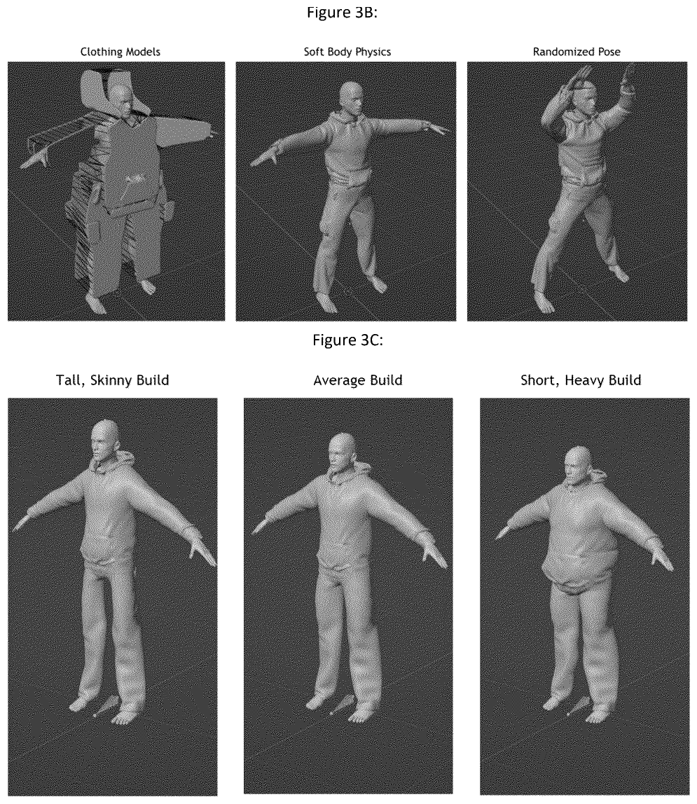

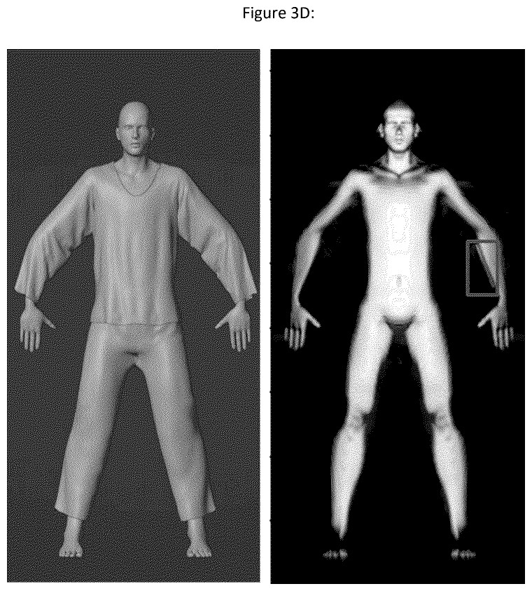

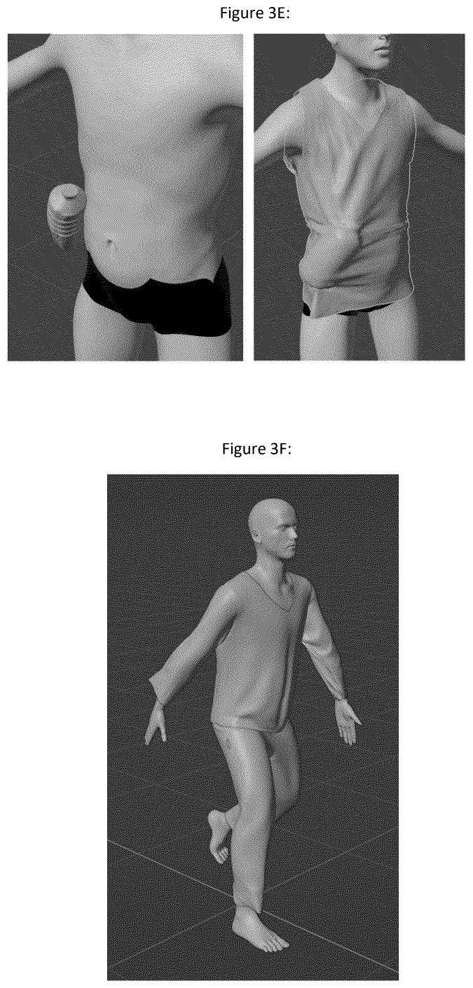

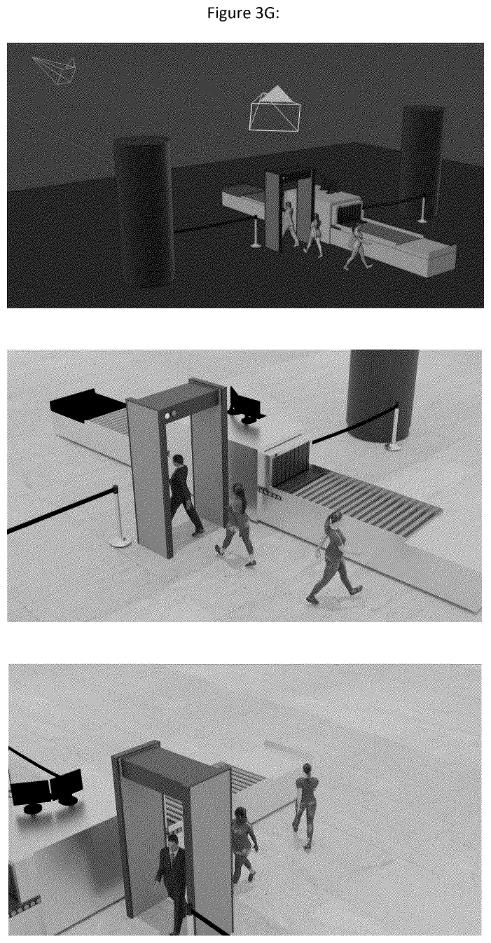

FIGS. 3A-3G illustrate synthetic millimeter wave and video surveillance imaging in accordance with an exemplary embodiment. Simulating synthetic passenger millimeter wave and video surveillance data requires access to a large library of three-dimensional (3D) human models representative of the wide variation in human anthropometric characteristics seen at security checkpoints. These passenger models also need to be representative of the variations in body pose that may be expected as passengers pass through the millimeter wave scanning system. Generating these population representative 3D models is a prerequisite to training robust Automatic Target Recognition (ATR) machine learning models that generalize well in production while also minimizing discriminatory bias.

However, generating sufficient number of population representative 3D models is a very time consuming task, and obtaining representative data by physical scanning may be difficult, which may lead to lower accuracy that may not be acceptable in performing security checks. For example, 3D models for various body types, body poses, walk cycles, and contraband placement on the body would need to be captured to serve as proper training data to provide reliable output by the ATR machine learning models. As illustrated in FIG. 3A, a person scanned may be scanned at different pose variations, and a potential contraband may be located at different locations (e.g., left ankle).

Passenger clothing items can present a significant challenge to ML based automated threat recognition algorithms. Clothing details such as folds of cloth, wired undergarments, zippers, or buttons may return reflected millimeter waves and present challenging and noisy artifacts in the reconstructed images. Capturing variation in clothing folds and related noise is critical for training robust automated threat recognition algorithms so that the models can learn to differentiate between noise and threat. As illustrated in FIG. 3B, a randomized passenger model may be automatically clothed with various clothing items from a library of object models using gravity and soft body physics simulation. Furthermore, generating a sufficient variation in clothing noise as passenger anthropometric measurements are varied is critical to model performance. As illustrated in FIG. 3C, clothing models are dynamically scaled with changes to the underlying measurements of the passenger model. FIG. 3D shows an example of 3D clothing models obscuring threat placement in a simulated millimeter wave image.

Automated threat recognition algorithms in passenger millimeter wave and video surveillance imaging systems require sufficient variation in threat placement and orientation on the body. Furthermore, improvised explosives present a unique challenge in that these threats conform to the human body and can take on variable shapes depending on their placement on the body. As illustrated in FIG. 3E, a system for randomized threat placement may be used with soft body physics simulation to place conformal threat models that plastically deform to follow the curvature of the human body.

Advancements in passenger millimeter wave screening systems are being made to speed up the stream-of-commerce, reduce passenger screening times, and improve the passenger experience. Walk-through millimeter wave imaging systems are a critical technology for reducing the screening burden. As illustrated in FIG. 3F, the passenger, threat, and clothing models may be animated using realistic human walk cycles to provide frame by frame 3D passenger models as input to millimeter wave simulation codes to support in-motion millimeter wave systems.

Automated threat recognition algorithms for video surveillance systems require operationally representative training data, including data that captures challenging environments with occlusion and crowds. As illustrated in FIG. 3G, a multitude of animated 3D passenger models may be placed in 3D scenes representative of operational environments with multi-view video surveillance cameras placed in different locations relative to the scene.

Although the above noted examples have been described with respect to generating synthetic training data for performing AI/ML enabled security screening of persons, aspects of the present disclosure are not limited thereto, such that the above noted technology may be applied for generating synthetic training data for AI/ML enabled radar based remote sensing and video surveillance applications (e.g., autonomous vehicles, military surveillance and targeting, crime prevention, traffic monitoring, and the like).

### Hybrid Synthetic Data Generation

While synthetic data is useful for training automated threat recognition algorithms using a variety of ML techniques, the synthetic data cannot capture the infinite variation and minute details of the physical world and therefore lacks realism to the human eye and limits the effectiveness of the data as a one-for-one replacement for real data. Furthermore, collecting positive scans of threat items is often impractical and dangerous. To address these issues, methods for inserting synthetically generated threats into real security imaging scans are possible. These methods identify or create empty space in real 3D baggage or passenger scans for insertion of simulated prohibited items.

### Technical Explanation

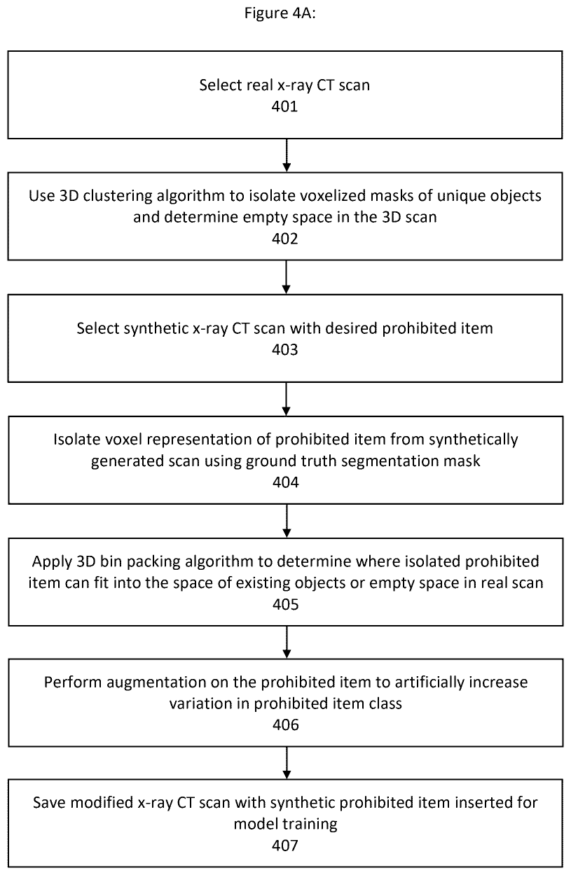

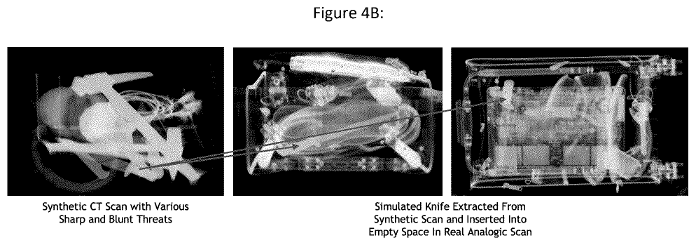

FIG. 4A illustrates a method for generating hybrid synthetic x-ray CT data.

In operation 401, selection of an acquired x-ray CT scan from a production system.

In operation 402, voxelized masks of objects inside the scan and empty space are calculated using a clustering algorithm. In an example, clustering algorithms may include spectral clustering and density-based clustering to determine locations inside of 3D baggage scans which have objects of significant size and/or density. From those density centers, nearby voxels may be searched and any that are touching the density center and are of similar enough density may be added. Such voxels may be considered as part of the same object.

In operation 403, a synthetically generated x-ray CT scan with prohibited item of interest is selected.

In operation 404, a prohibited item from a synthetically generated scan is isolated using ground truth segmentation annotation. The original objects included in a scanned image are replaced with other objects from the object library to generate a completely novel 3D scan.

In operation 405, a 3D bin-packing algorithm is applied to determine where the synthetic prohibited item can fit into empty space or replace an existing object in the real scan. In an example, 3D bin-packing algorithms may include greedy algorithms, heuristic algorithms, reinforcement learning algorithms, and genetic algorithms.

In operation 406, any number of augmentations on the prohibited item may be performed. In an example, augmentations may include rotations, density changes, blurring, and the like.

In operation 407, and as shown in FIG. 4B, an augmented synthetic prohibited item is inserted into the voxel representation of the original real scan with ground truth location and saved for ML model training.

### INDUSTRIAL APPLICATION

According to exemplary aspects, the above noted 3D hybrid synthetic dataset generation methodology may be applied to any 3D vision ML context, as these models typically require enormous amounts of data that are difficult to acquire. Moreover, the 3D dataset generation methodology may have a strong application in industries where real data cannot be shared due to privacy concerns, such as medical imaging. In addition, the 3D dataset generation methodology may be particularly useful for increasing the available data for rare-occurring objects. For example, in medical field applications, a rare brain tumor may be augmented and placed into millions of scans of healthy brains to give vision models more unique, high-quality data to learn from.

Although the devices, methods, and/or systems have been described with reference to several exemplary embodiments, it is understood that the words that have been used are words of description and illustration, rather than words of limitation. Changes may be made within the purview of the appended claims, as presently stated and as amended, without departing from the scope and spirit of the present disclosure in its aspects. Although the devices, methods, and/or systems have been described with reference to particular means, materials and embodiments, the devices, methods, and/or systems are not intended to be limited to the particulars disclosed; rather the devices, methods, and/or systems extend to all functionally equivalent structures, methods, and uses such as are within the scope of the appended claims.

For example, while the computer-readable medium may be described as a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the embodiments disclosed herein.

The computer-readable medium may comprise a non-transitory computer-readable medium or media and/or comprise a transitory computer-readable medium or media. In a particular non-limiting, exemplary embodiment, the computer-readable medium can include a solid-state memory such as a memory card or other package that houses one or more non-volatile read-only memories. Further, the computer-readable medium can be a random access memory or other volatile re-writable memory.

Additionally, the computer-readable medium can include a magneto-optical or optical medium, such as a disk or tapes or other storage device to capture carrier wave signals such as a signal communicated over a transmission medium. Accordingly, the disclosure is considered to include any computer-readable medium or other equivalents and successor media, in which data or instructions may be stored.

Although the present application describes specific embodiments which may be implemented as computer programs or code segments in computer-readable media, it is to be understood that dedicated hardware implementations, such as application specific integrated circuits, programmable logic arrays and other hardware devices, can be constructed to implement one or more of the embodiments described herein. Applications that may include the various embodiments set forth herein may broadly include a variety of electronic and computer systems. Accordingly, the present application may encompass software, firmware, and hardware implementations, or combinations thereof. Nothing in the present application should be interpreted as being implemented or implementable solely with software and not hardware.

Although the present specification describes components and functions that may be implemented in particular embodiments with reference to particular standards and protocols, the disclosure is not limited to such standards and protocols. Such standards are periodically superseded by faster or more efficient equivalents having essentially the same functions. Accordingly, replacement standards and protocols having the same or similar functions are considered equivalents thereof.

It is understood that embodiments presented herein are meant to be exemplary. Embodiments of the present disclosure can comprise any combination of compatible features and steps, and these embodiments should not be limited to those expressly illustrated and discussed. For instance and not by way of limitation, the appended claims could be modified to be multiple dependent claims so as to combine any combinable combination of elements within a claim set, or from differing claim sets. Claims depending on one independent claim (e.g., claim 1) could be modified so as to depend from a different independent claim (e.g., claim 20), and one type of independent claim (e.g., a method claim like claim 20) could be modified to be a system or medium claim. Although the present disclosure has been described in detail with reference to certain preferred configurations thereof, other versions are possible. Therefore, the spirit and scope of the disclosure should not be limited to the specific versions described above.

While the foregoing written description of the disclosure enables one of ordinary skill to make and use what is considered presently to be the best mode thereof, those of ordinary skill will understand and appreciate the existence of variations, combinations, and equivalents of the specific embodiments, methods, systems, and examples herein. The disclosure should therefore not be limited by the above described embodiments, methods, systems, and examples. Furthermore, certain terminology has been used for the purposes of descriptive clarity, and not to limit the present disclosure. It is therefore intended that the following appended claims include all such alterations, modifications and permutations as fall within the true spirit and scope of the present disclosure. No portion of the disclosure is intended, expressly or implicitly, to be dedicated to the public domain if not set forth in the claims.

The illustrations or figures of the embodiments described herein are intended to provide a general understanding of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

We claim:

1. A system for generating a large volume of synthetic stream-of-commerce security imaging data comprising:
a user interface configured to accept a user's specification of modeling parameters and simulation parameters; and
a non-transitory computer-readable media operably connected to said user interface and encoding a set of non-transitory computer-readable instructions, which when executed on one or more processors cause:
inputting said specification of modeling parameters and simulation parameters;
generation of synthetic scans;
performance of 3D modeling and simulation to generate randomized models based on said modeling parameters;
passing of said randomized models to physics-based simulation codes for generating simulated image system outputs based on said simulation parameters; and
generation of ground truth annotations of said randomized models based on said modeling parameters and simulation parameters.

2. The system of claim 1, wherein a cloud-based web application comprises said set of non-transitory computer-readable instructions, said instructions further comprising:
orchestrating on-demand cloud compute resources for batch generation of a dataset.

3. The system of claim 2, wherein said user interface is a web user interface.

4. The system of claim 2, wherein said user interface is an application programming interface.

5. The system of claim 1, wherein the execution of said non-transitory computer-readable instructions further cause:
collation, storage, and making available to users said one or more completed images.

6. The system of claim 1, wherein said randomized models are passenger models.

7. The system of claim 1, wherein said randomized models are baggage models.

8. The system of claim 1, wherein said modeling parameters comprise at least one of benign item classes, prohibited item classes, custom prohibited item model specification, prohibited item distribution, packing algorithm specification, passenger anthropometric measurement distributions, passenger resting pose distribution, and passenger walk cycle animations.

9. The system of claim 1, wherein said simulation parameters comprise at least one of source energy spectra, imaging geometry, detector geometry, detector element and transceiver properties, 3D reconstruction algorithms, and material properties.

10. A non-transitory computer-readable media encoding a set of non-transitory computer-readable instructions, which when executed on one or more processors cause:
the inputting of user specification of modeling parameters and simulation parameters;
generation of synthetic scans;
performance of 3D modeling and simulation to generate randomized models based on said modeling parameters;
passing of said randomized models to physics-based simulation codes for generating simulated image system outputs based on said simulation parameters; and
generation of ground truth annotations of said randomized models based on said modeling parameters and simulation parameters.

11. A method for creating synthetic scans comprising:
obtaining a real scan and a synthetic scan having a prohibited item;
using a clustering algorithm to isolate voxelized masks of unique objects and empty space in said real scan;
using a truth segmentation mask to isolate the voxel representation of said prohibited item from said synthetic scan;
applying a 3D bin packing algorithm to determine the location in which said prohibited item may fit in said real scan;
performing augmentation on said prohibited item;
inserting said prohibited item in said voxelized masks to create a modified scan; and
saving said modified scan for use in model training.

12. The method of claim 11, wherein said real scan is an x-ray scan.

13. The method of claim 11, wherein said real scan is a CT scan.

14. The method of claim 11, wherein said real scan is a millimeter wave scan.

15. The method of claim 11, wherein said real scan is a video image.

16. The method of claim 11, wherein said location is within said unique objects.

17. The method of claim 11, wherein said location is within said empty space.

18. The method of claim 11, wherein said augmentation comprises rotation.

19. The method of claim 11, wherein said augmentation comprises changing the density of said prohibited item.

20. The method of claim 11, wherein said augmentation comprises blurring said prohibited item.
